(19) United States
(12) Patent Application Publication
(10) Pub. No.: US 2026/0114140 A1
(43) Pub. Date: Apr. 23, 2026

(54) DISPLAY DEVICE INCLUDING PADS, ELECTRONIC APPARATUS, AND ELECTRONIC DEVICE INCLUDING THE SAME

(71) Applicant: SAMSUNG DISPLAY CO., LTD., YONGIN-SI (KR)

(72) Inventors: EUNBYUL KIM, Yongin-si (KR); HANBUM KWON, Yongin-si (KR); YOUNGMIN AHN, Yongin-si (KR)

(21) Appl. No.: 19/269,245

(22) Filed: Jul. 15, 2025

(30) Foreign Application Priority Data
Oct. 17, 2024 (KR) 10-2024-0142321

(51) Int. Cl. H10K 59/131

(52) U.S. Cl. CPC H10K 59/131

(57) ABSTRACT

A display device includes a display panel including a plurality of pixels. A display device includes a pad area including a plurality of pads disposed therein. A display device includes a driver chip disposed on the pad area and electrically connected to the plurality of pads and to the plurality of pixels. A display device includes a dummy pad spaced apart from the plurality of pads. A display device includes an alignment pad surrounding the dummy pad.

### CROSS-REFERENCE TO RELATED APPLICATIONS

This U.S. non-provisional patent application claims priority under 35 U.S.C. § 119 to Korean Patent Application No. 10-2024-0142321, filed on Oct. 17, 2024, in the Korean Intellectual Property Office, the disclosure of which is incorporated by reference herein in its entirety.

### TECHNICAL FIELD

The present disclosure herein relates to a display device, and more specifically, to a display device including pads, an electronic apparatus, and an electronic device including the same.

In general, electronic devices such as smart phones, digital cameras, laptop computers, navigation systems, and smart televisions include a display device for displaying images to users. The display device generates an image and provides the image to a user through a display screen.

Display devices include a display panel including pixels and a driver connected to the display panel and configured to drive the pixels. The driver may be directly mounted on a substrate of the display panel and electrically connected to the display panel. In addition, the driver may be mounted on a flexible circuit board, and electrically connected to the display panel through the flexible circuit board.

A display panel may include pads and a driver may include chip pads. An electrical connection between the pads of the display panel and the chips pads of the driver should be stable. When a pressurization process for connecting the pads of the display panel and the chip pads of the driver is performed, flatness of the display panel may be distorted due to uneven pressure. As the unevenness of the display panel increases, some pads might not connect with the chip pads as desired. Thus, the degree of unstableness of the electrical connection between the pads of the display panel and the chips pads of the driver may increase.

### SUMMARY

According to an embodiment of the disclosure, a display device includes a display panel including a plurality of pixels. A display device includes a pad area including a plurality of pads disposed therein. A display device includes a driver chip disposed on the pad area and electrically connected to the plurality of pads and to the plurality of pixels. A display device includes a dummy pad spaced apart from the plurality of pads. A display device includes an alignment pad surrounding the dummy pad.

In an embodiment, the alignment pad may include a metal layer.

In an embodiment, the alignment pad may be disposed below the dummy pad.

In an embodiment, the dummy pad may include a polymer.

In an embodiment, the alignment pad may include a same material as a gate electrode of a transistor of one of the plurality of pixels. The alignment pad and the gate electrode may be disposed within a same layer.

In an embodiment, a thickness of the alignment pad may be less than a thickness of the dummy pad.

In an embodiment, the alignment pad may be electrically disconnected from the plurality of pixels.

In an embodiment, the driver chip may include bump pads electrically connected to the plurality of pads. The driver chip may include a dummy bump pad electrically connected to the dummy pad.

In an embodiment, the dummy bump pad may be pressure bonded to the dummy pad and the dummy pad may contract in a direction perpendicular to an upper surface of the display panel.

In an embodiment, an upper surface of the display panel may be a plane defined by a first direction and a second direction intersecting the first direction, and the dummy pad may be adjacent to an edge of the pad area in the second direction.

In an embodiment, the dummy bump pad may be pressure bonded to the alignment pad and the dummy pad may be expanded in the second direction.

In an embodiment, each of the plurality of pads may include a first electrode, a second electrode disposed on the first electrode and electrically connected to the first electrode, a third electrode disposed on the second electrode and electrically connected to the second electrode, and a buffer pad disposed between the second electrode and the third electrode. Each of the bump pads may be disposed on a third electrode of a corresponding pad among the plurality of pads and may be electrically connected to the third electrode of the corresponding pad of the plurality of pads.

In an embodiment, the dummy pad may include a same material as the buffer pad.

In an embodiment, the display device may include a pressure distribution pad adjacent to the dummy pad.

In an embodiment, the pressure distribution pad may include a (1-1)-th electrode, a (2-1)-th electrode disposed on the (1-1)-th electrode, a (3-1)-th electrode disposed on the (2-1)-th electrode, and a dummy buffer pad disposed between the second electrode and the third electrode.

In an embodiment, the display device may include a dummy metal layer disposed on the dummy pad.

In an embodiment, the dummy pad may be provided in plural in a window region defined by the alignment pad.

In an embodiment, the dummy pad may be elastic and may be configured to be deformed by compressive force.

According to an embodiment of the disclosure, an electronic apparatus includes a display device including a first hole region configured to pass light therethrough, an electro-optical circuit disposed under the display device to overlap the first hole region, and configured to receive a light signal. An electronic apparatus includes a case configured to accommodate the display device and the electro-optical circuit. The display device includes a display panel including a plurality of pixels and a pad area electrically connected to the plurality of pixels, and a driver chip disposed on the pad area and electrically connected to the pad area. The pad area includes a plurality of pads electrically connected to the plurality of pixels and to the driver chip, a dummy pad spaced apart from the plurality of pads, and an alignment pad surrounding the dummy pad.

According to an embodiment of the disclosure, an electronic device includes a display device including a first hole region configured to allow light to pass through. An electronic device includes an electro-optical circuit disposed under the display device to overlap the first hole region, and configured to receive a light signal. An electronic device includes a case accommodating the display device and the electro-optical circuit. The display device includes a display panel including a plurality of pixels and a pad area electrically connected to the plurality of pixels. The display device includes a driver chip disposed on the pad area and electrically connected to the pad area. The pad area includes a plurality of pads electrically connected to the plurality of pixels and to the driver chip. The pad area includes a dummy pad spaced apart from the plurality of pads, and an alignment pad surrounding the dummy pad.

### BRIEF DESCRIPTION OF THE FIGURES

A more complete appreciation of the present disclosure and many of the attendant aspects thereof will be readily obtained as the same becomes better understood by reference to the following detailed description when considered in connection with the accompanying drawings, wherein:

FIG. 1 is a perspective view of a display device, according to an embodiment of the disclosure;

FIG. 2 is a cross sectional view of the display device illustrated in FIG. 1, according to an embodiment of the disclosure;

FIG. 3 is a cross sectional view of a display panel illustrated in FIG. 2, according to an embodiment of the disclosure;

FIG. 4 is an exploded perspective view of an electronic apparatus illustrated in FIG. 1, according to an embodiment of the disclosure;

FIG. 5 is a block diagram of the electronic apparatus illustrated in FIG. 4, according to an embodiment of the disclosure;

FIG. 6 is a plan view of the display panel illustrated in FIG. 3, according to an embodiment of the disclosure;

FIG. 7 is a cross sectional view of a pixel illustrated in FIG. 6, according to an embodiment of the disclosure;

FIG. 8 is a plan view of a first pad area illustrated in FIG. 6, according to an embodiment of the disclosure;

FIG. 9 is a planar configuration of one of the pads illustrated in FIG. 8, according to an embodiment of the disclosure;

FIG. 10 is a cross-sectional view of a first pad area taken along the line I-I′ of FIG. 9, according to an embodiment of the disclosure;

FIG. 11 is a cross-sectional view of a second pad area taken along the line II-II′ of FIG. 9, according to an embodiment of the disclosure;

FIG. 12 is a cross-sectional view of a first pressure distribution pad taken along the line x-x′ of FIG. 8, according to an embodiment of the disclosure;

FIG. 13 is a cross-sectional view of a first alignment pad and a dummy pad taken along the line y-y′ of FIG. 8, according to an embodiment of the disclosure;

FIG. 14 is a view illustrating a pad disposed on a display panel illustrated in FIG. 10 coupled to a chip pad disposed on a driver chip, according to some embodiments of the disclosure;

FIG. 15 is a view illustrating the first alignment pad illustrated in FIG. 13 coupled to a chip pad disposed on a driver chip, according to some embodiments of the disclosure;

FIG. 16 is a view illustrating first and second dummy pads captured by a measuring device, according to an embodiment of the disclosure;

FIG. 17A is a view illustrating a first dummy panel pad according to an embodiment of the disclosure, and FIG. 17B is a cross-sectional view illustrating a first pressure distribution pad taken along the line z-z′ of FIG. 17A;

FIGS. 18A and 18B are views illustrating a first dummy pad according to an embodiment of the disclosure; and

FIG. 19 is a diagram illustrating an electronic device according to an embodiment of the disclosure.

### DETAILED DESCRIPTION

The present invention will now be described more fully hereinafter with reference to the accompanying drawings, in which embodiments of the invention are shown. This invention may, however, be embodied in different forms and should not necessarily be construed as limited to the embodiments set forth herein.

Embodiments of the present disclosure are described with the understanding that when an element (or a region, a layer, a portion, or the like) is referred to as being “on”, “connected to” or “coupled to” another element, it may be directly disposed on, connected to, or coupled to the other element, or other elements may be disposed therebetween. For example, intervening layers, areas, or elements may be present therebetween. However, when an element is referred to as being “directly on,” “directly connected to,” or “directly coupled to” another element, there might be no intervening elements present.

Like reference numerals or symbols may refer to like elements throughout the specification and the drawings. Also, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

As used herein, the term “and/or” includes any and all combinations of one or more of the associated listed elements.

Although the terms “first”, “second”, etc. may be used herein to describe various elements, these elements, should not necessarily be limited by these terms. These terms may be used to distinguish one element from another element. Thus, a first element discussed below may be termed a second element without departing from the teachings of one or more embodiments. The description of an element as a “first” element might not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

The terminology used herein is for the purpose of describing example embodiments only and is not necessarily intended to be limiting of the present inventive concept. As used herein, the singular expressions “a,” “an,” and “the” may be intended to include the plural forms as well, unless the context clearly indicates otherwise.

In addition, spatially relative terms such as “below”, “at the bottom”, “lower”, “below”, “above”, “on top”, “on the top”, “on”, etc., are used to explain a relationship between components shown in the drawings. The terms are relative concepts and are explained based on the direction indicated in the drawings. Spatially relative terms are intended to include other directions in use, in operation, and/or in manufacturing, in addition to the direction depicted in the drawings. For example, in case that a device shown in the drawing is turned upside down, elements depicted as being positioned “under” other elements or features are positioned in a direction “on” the other elements or features. Therefore, in an embodiment, the term “under” may include both directions of “on” and “under”.

The terms “includes,” “comprises,” “having,” and/or “comprising”, when used herein, specify the presence of stated features, integers, steps, operations, elements, and/or components, but do not necessarily preclude the presence or addition of one or more other features, integers, steps, operations, elements, components, and/or groups thereof.

Traditionally, a display device may include a display panel. However, during manufacturing, the display panel may be distorted, for example, the display panel might not be substantially flat, as desired.

To overcome these challenges, a display panel may include one or more dummy pads. The change in the size/area of the dummy pad may be measured during manufacturing to ensure flatness of the display panel. For example, the flatness of the display panel may be inferred from the amount of change in the measured dummy pad.

Hereinafter, embodiments of the present invention are described with reference to the drawings.

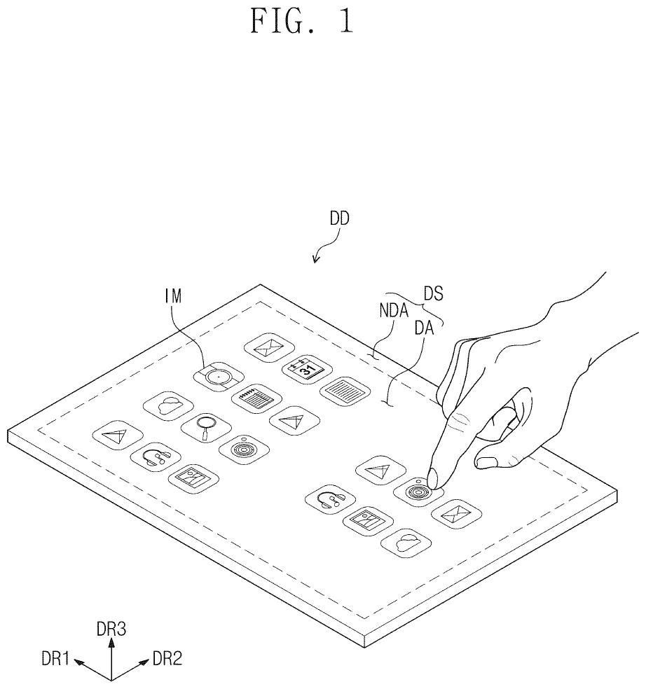

FIG. 1 is a perspective view of a display device according to an embodiment of the disclosure.

Referring to FIG. 1, a display device DD, according to an embodiment of the disclosure, may have a rectangular shape having a pair of comparatively longer sides extending in a first direction DR1 and a pair of shorter sides extending in a second direction DR2. The first direction DR1 may intersect the second direction DR2. However, an embodiment of the disclosure is not necessarily limited thereto, and the display device DD may have various shapes such as circular or polygonal shapes.

Hereinafter, a direction substantially perpendicularly intersecting a plane defined by the first direction DR1 and the second direction DR2 is defined as a third direction DR3. Numerous embodiments of the disclosure are described with the understanding that the wording “when viewed on a plane” or “in a plan view” is defined as a state viewed from the third direction DR3.

An upper surface of the display device DD may be defined as a display surface DS, and may have a plane defined by the first direction DR1 and the second direction DR2. Images IM generated in the display device DD may be provided to a user through the display surface DS.

The display surface DS may include a display region DA and a non-display region NDA proximate to the display region DA. The display region DA may display an image and the non-display region NDA might not display an image. The non-display region NDA may surround the display region DA and define an edge of the display device DD. For example, the non-display region NDA may be adjacent to the display region DA.

The display device DD may be used in large-sized electronic apparatuses such as televisions, computer monitors, or outdoor digital billboards. In some embodiments, the display device DD may also be used in small-and medium-sized electronic apparatuses such as laptop/notebook computers, personal digital assistants, car navigation systems, portable game consoles, smartphones, tablet computers, or digital cameras. However, such apparatuses are presented as examples only, and the display device may also be used in other electronic apparatuses unless deviating from the idea of the inventive concept.

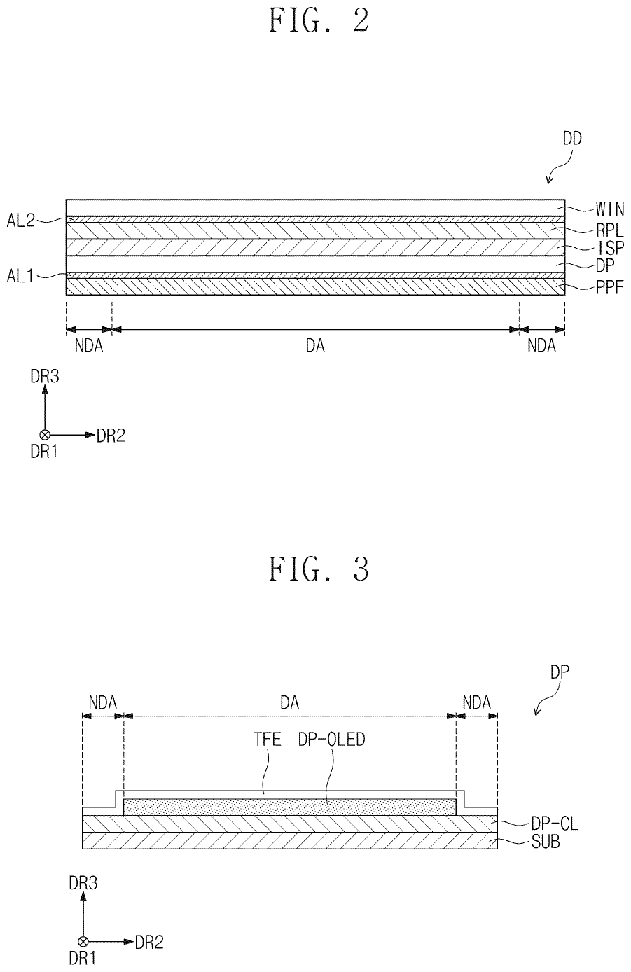

FIG. 2 is a cross-sectional view illustrating the display device illustrated in FIG. 1.

For example, FIG. 2 illustrates a cross section of a display device DD viewed from a first direction DR1.

Referring to FIG. 2, the display device DD may include a display panel DP, an input sensing part ISP, an anti-reflection layer RPL, a window WIN, a panel protection film PPF, a first adhesive layer AL1, and a second adhesive layer AL2.

The display panel DP may be a flexible display panel. For example, the display panel DP may be bent to at least a noticeable degree without being damaged. The display panel DP, according to an embodiment of the disclosure, may be an emissive display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, and the like. In numerous embodiments, the display panel DP of the display device DD is an organic light-emitting display panel.

The input sensing part ISP may be disposed on the display panel DP. The input sensing part ISP may include a plurality of sensing parts for sensing an external input in a capacitive manner. The input sensing part ISP may be manufactured directly on the display panel DP during the manufacture of the display device DD. However, an embodiment of the disclosure is not necessarily limited thereto, and the input sensing part ISP may be manufactured as a separate panel from the display panel DP, and attached to the display panel DP by an adhesive layer.

The anti-reflection layer RPL may be disposed on the input sensing part ISP. The anti-reflection layer RPL may be manufactured directly on the input sensing part ISP during the manufacture of the display device DD. However, an embodiment of the disclosure is not necessarily limited thereto, and the anti-reflection layer RPL may be manufactured as a separate panel and attached to the input sensing part ISP by an adhesive layer.

The anti-reflection layer RPL may be defined as an anti-reflection film for blocking the reflection of ambient light. The anti-reflection layer RPL may reduce reflectance for the ambient light incident toward the display panel DP from above the display device DD. The ambient light might not be visible to a user due to the anti-reflection layer RPL.

When the ambient light propagating toward the display panel DP is reflected from the display panel DP and provided back to a user of the display panel DP, the user may view the ambient light, as if the display panel is a mirror. To prevent such a phenomenon, for example, the anti-reflection layer RPL may include a plurality of color filters for displaying colors which are the same as those of pixels of the display panel DP.

The color filters may filter ambient light into the same colors as those of the pixels. In such cases, the ambient light may be invisible to a user. However, an embodiment of the disclosure is not necessarily limited thereto, and the anti-reflection layer RPL may include a retarder (for e.g., a phase retarder) and/or a polarizer so as to reduce ambient light reflectance.

The window WIN may be disposed on the anti-reflection layer RPL. The window WIN may protect the display panel DP, the input sensing part ISP, and the anti-reflection layer RPL from an external impact and/or scratches.

The panel protection film PPF may be disposed under the display panel DP. The panel protection film PPF may protect a lower part of the display panel DP. The panel protection film PPF may include a flexible plastic material such as polyethylene terephthalate (PET).

The first adhesive layer AL1 may be disposed between the display panel DP and the panel protection film PPF, and the display panel DP and the panel protection film PPF may be bonded to each other by the first adhesive layer AL1. The second adhesive layer AL2 may be disposed between the window WIN and the anti-reflection layer RPL, and the window WIN and the anti-reflection layer RPL may be bonded to each other by the second adhesive layer AL2.

FIG. 3 is a cross sectional view of the display panel illustrated in FIG. 2.

For example, FIG. 3 illustrates a cross section of a display panel DP viewed from a first direction DR1.

Referring to FIG. 3, the display panel DP may include a substate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA proximate to the display region DA. The substrate SUB may include glass or a flexible plastic material such as polyimide (PI). The display element layer DP-OLED may be disposed in the display region DA.

A plurality of pixels may be disposed on the circuit element layer DP-CL and the display element layer DP-OLED. The pixels may each include a transistor disposed on the circuit element layer DP-CL and a light-emitting element disposed on the display element layer DP-OLED and electrically connected to the transistor.

The thin-film encapsulation layer TFE may be disposed on the circuit element layer DP-CL to cover the display element layer DP-OLED. The thin-film encapsulation layer TFE may protect the pixels from moisture, oxygen, and materials/particles foreign to the pixels.

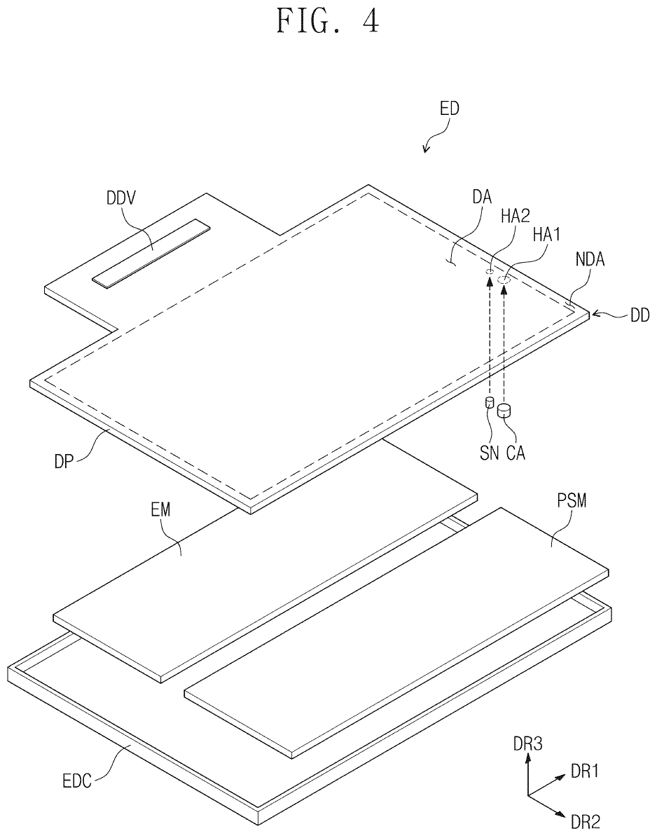

FIG. 4 is an exploded perspective view of an electronic apparatus including the display device illustrated in FIG. 1.

Referring to FIG. 4, an electronic apparatus ED may include a display device DD, a camera CA, a sensor SN, an electronic module EM, a power supply module PSM, and a case EDC.

A first hole region HA1 and a second hole region HA2 may be defined in the display device DD. The first hole region HA1 and the second hole region HA2 may have a higher light transmittance than the surroundings of the hole regions. The camera CA may be disposed under the first hole region HA1 and the sensor SN may be disposed under the second hole region HA2. Light transmitted through the first and the second hole regions HA1 and HA2 may be provided to the camera CA and the sensor SN. In some embodiments, light passing through the first and the second hole regions HA1 and HA2 may be provided to the camera CA and the sensor SN.

The electronic module EM and the power supply module PSM may be disposed under the display device DD. In some embodiments, the electronic module EM and the power supply module PSM may be electrically connected to each other through a separate flexible circuit board. The electronic module EM may control one or more operations of the display device DD. The power supply module PSM may supply power to the electronic module EM.

The case EDC may accommodate the display device DD, the electronic module EM, and the power supply module PSM.

The case EDC may protect the display device DD, the electronic module EM, and the power supply module PSM from being damaged.

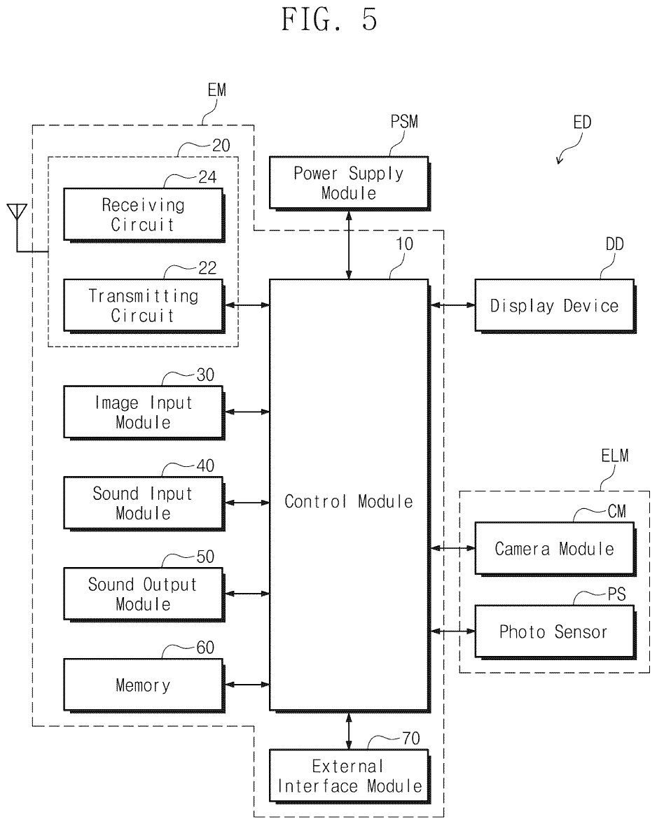

FIG. 5 is a block diagram of the electronic apparatus illustrated in FIG. 4.

Referring to FIG. 5, an electronic apparatus ED may include an electronic module EM, a power supply module PSM, a display device DD, and an electro-optical module ELM. The electronic module EM may include a control module 10, a wireless communication module 20, an image input module 30, a sound input module 40, a sound output module 50, a memory device 60, an external interface module 70, and the like. The modules may be mounted on a circuit board, or electrically connected through a flexible circuit board. The electronic module EM may be electrically connected to the power supply module PSM.

The control module 10 may control overall operations of the electronic apparatus ED. For example, the control module 10 may activate or deactivate the display device DD in accordance with a user's input. The control module 10 may control the image input module 30, the sound input module 40, the sound output module 50, and the like in accordance with a user's input. The control module 10 may include at least one microprocessor.

The wireless communication module 20 may transmit/receive a wireless signal to/from another terminal using a Bluetooth or Wi-Fi line. The wireless communication module 20 may transmit/receive a voice signal using a general communication line. The wireless communication module 20 may include a transmitting circuit 22 which modulates and transmits a signal to be transmitted, and a receiving circuit 24 which demodulates the received signal.

The image input module 30 may process an image signal and convert the signal into image data displayable on the display device DD. The sound input module 40 may receive an external sound signal through a microphone in a recording mode, a voice recognition mode, or the like, and may convert the signal into electrical voice data. The sound output module 50 may convert the sound data received from the wireless communication module 20 or the sound data stored in the memory 60 and output the data to an external source and/or a user.

The external interface module 70 may serve as an interface connected to an external charger, a wired/wireless data port, a card socket (for example, a memory card, SIM/UIM card socket), and the like.

The power supply module PSM may supply power that is necessary for overall operations of the electronic apparatus ED. The power supply module PSM may include a battery unit.

The electro-optical module ELM may be an electronic component that outputs or receives light signal. The electro-optical module ELM may transmit or receive light signal through a region or a part of the display device DD. In an embodiment, the electro-optical module ELM may include a camera module CM and a photo sensor PS. The camera module CM may include the camera CA illustrated in FIG. 4. The photo sensor PS may include the sensor SN illustrated in FIG. 4.

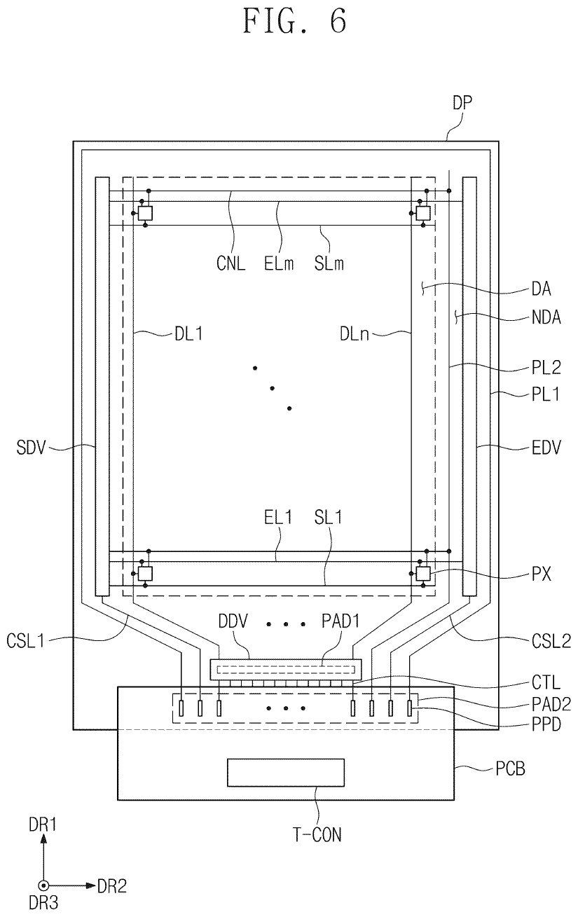

FIG. 6 is a plan view of the display panel illustrated in FIG. 3.

Referring to FIG. 6, a display device DD may include a display panel DP, a scan driver SDV, a data driver DDV, an emission driver EDV, a printed circuit board PCB, and a timing controller T-CON. In some embodiments, the data driver DDV may be a driver chip. Hereinafter, the data driver DDV will be referred to as a driver chip.

The display panel DP may have a rectangular shape having a pair of longer sides extending in a first direction DR1 and a pair of comparatively shorter sides extending in a second direction DR2. The display panel DP may include a display region DA and a non-display region NDA surrounding the display region DA.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a first power supply line PL1, a second power supply line PL2, connection lines CNL, and first and second pad parts PAD1 and PAD2, respectively, where m and n are positive integers. The lines may be disposed in a circuit element layer DP-CL. In an embodiment, the first and second pad parts (PAD1 and PAD2) may be referred to as the first and second pad areas, respectively

The pixels PX may be disposed in the display region DA. The scan driver SDV, the driver chip DDV, and the emission driver EDV may be disposed in the non-display region NDA. For example, the scan driver SDV and the emission driver EDV may be disposed in the non-display region NDA adjacent to the pair of respective longer sides of the display panel DP.

The driver chip DDV may form of an integrated circuit chip and mounted on the display panel DP. The driver chip DDV may be disposed on the non-display region NDA adjacent to any one of the pair of shorter sides of the display panel DP, as described with reference to FIG. 1 above. However, an embodiment of the disclosure is not necessarily limited thereto, and the driver chip DDV may be mounted on a flexible circuit board connected to the display panel DP. In some embodiments, the driver chip DDV may be connected to the display panel DP through the flexible circuit board. For example, when viewed on a plane, the driver chip DDV may be adjacent to a lower end of the display panel DP.

The scan lines SL1 to SLm, where m is a positive integer, may extend in the second direction DR2 and may be connected to the pixels PX and the scan driver SDV. The data lines DL1 to DLn, where n is a positive integer, may extend in the first direction DR1 and may be connected to the pixels PX and the driver chip DDV. The emission lines EL1 to Elm, where m is a positive integer, may extend in the second direction DR2 and may be connected to the pixels PX and the emission driver EDV.

The first power supply line PL1 may be disposed in the non-display region NDA. The first power supply line PL1 may extend along an edge of the display panel DP. The first power supply line PL1 may be adjacent to the pair of longer sides of the display panel DP, as described with reference to FIG. 1 above. In some embodiments, the first power supply line PL1 may be adjacent to another shorter side of the display panel DP where the driver chip DDV is not disposed. The first power supply line PL1 may be disposed outside the scan driver SDV and the emission driver EDV.

The first power supply line PL1 may receive a first voltage. For example, the first power supply line PL1 may extend to the display region DA and may be connected (for e.g., electrically) to the pixels PX, and the first voltage may be provided to the pixels PX through the first power supply line PL1.

The second power supply line PL2 may extend in the first direction DR1 and may be disposed in the non-display region NDA. The second power supply line PL2 may be disposed between the display region DA and the emission driver EDV. However, an embodiment of the disclosure is not necessarily limited thereto, and the second power supply line PL2 may be disposed between the display region DA and the scan driver SDV. The second power supply line PL2 may receive a second voltage that has a value greater than the value of the first voltage.

The connection lines CNL may extend in the second direction DR2 and may be arranged in the first direction DR1. The connection lines CNL may be electrically connected to the second power supply line PL2 and the pixels PX. The second voltage may be applied to the pixels PX through the second power supply line PL2 and the connection lines CNL. In some embodiments, the second power supply line PL2 and the connection lines CNL may be connected to each other.

The first control line CSL1 may be electrically connected to the scan driver SDV, and when viewed on a plane, may extend toward the lower end of the display panel DP. The second control line CSL2 may be electrically connected to the emission driver EDV, and when viewed on a plane, may extend toward the lower end of the display panel DP. The driver chip DDV may be disposed between the first control line CSL1 and the second control line CSL2.

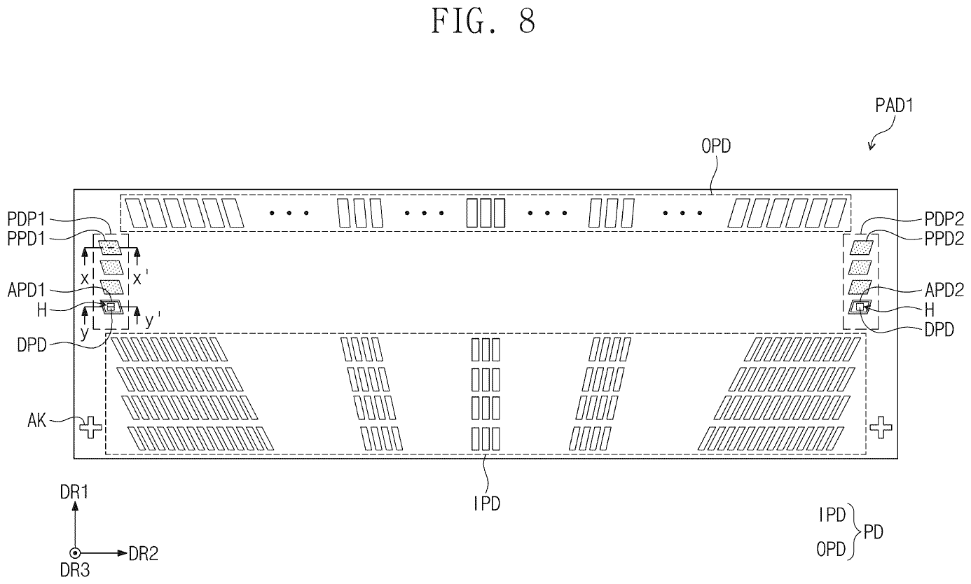

The first pad part PAD1 may overlap the driver chip DDV. The first pad part PAD1 may be disposed under the driver chip DDV and may be connected (for e.g., electrically) to the driver chip DDV. In an embodiment, the first pad part PAD1 may include a plurality of pads, and a configuration of the pads will be described in more detail later with reference to FIG. 8.

The second pad part PAD2 may be disposed adjacent to a lower side of the display panel DP. For example, the second pad part PAD2 may be disposed closer to a lower side of the display panel DP than the driver chip DDV. The second pad part PAD2 may be electrically connected to the first pad part PAD1 disposed under the driver chip DDV. For example, the second pad part PAD2 may be electrically connected to the first pad part PAD1 through connection wiring CTL. The driver chip DDV may be electrically connected to the second pad part PAD2 through the first pad part PAD1 and the connection wiring CTL.

The second pad part PAD2 may include a plurality of panel pads PPD. The panel pads PPD of the second pad part PAD2 may be arranged in the second direction DR2. The driver chip DDV, the first power supply line PL1, the second power supply line PL2, the first control line CSL1, and the second control line CSL2 may be connected (for e.g., electrically) to the panel pads PPD of the second pad part PAD2.

The data lines DL1 to DLn, where n is a positive integer, may be electrically connected to the driver chip DDV through the first pad part PAD1. In an embodiment, the first pad part PAD1 may be electrically connected to the pixels PX through the data lines DL1 to DLn, where n is a positive integer.

The timing controller T-CON may be disposed on the printed circuit board PCB. The timing controller T-CON may be manufactured as an integrated circuit chip and mounted on the printed circuit board PCB.

The printed circuit board PCB may be electrically connected to the panel pads PPD of the second pad part PAD2. The printed circuit board PCB may be electrically connected to the display panel DP through the second pad part PAD2. The timing controller T-CON may be electrically connected to the panel pads PPD. For example, the timing controller T-CON may be connected to the display panel DP through the panel pads PPD.

In some embodiments, since the panel pads PPD may be electrically connected to the first pad part PAD1, the printed circuit board PCB may be connected to the driver chip DDV. In an embodiment, the printed circuit board PCB may be electrically connected to the first and second power supply lines PL1 and PL2, and the first and second control lines CSL1 and CSL2, through the panel pads PPD.

The timing controller T-CON may control operations of the scan driver SDV, the driver chip DDV, and the emission driver EDV. The timing controller T-CON may generate a scan control signal, a data control signal, and an emission control signal in response to control signals received from an external source.

The scan control signal may be provided to the scan driver SDV through the first control line CSL1. The emission control signal may be provided to the emission driver EDV through the second control line CSL2. The data control signal may be provided to the driver chip DDV. The timing controller T-CON may receive image signals from an external source, and may convert data formats of the image signals to comply with an interface specification for the driver chip DDV and provide converted image signals to the driver chip DDV.

The scan driver SDV may generate a plurality of scan signals in response to the scan control signal. The scan signals may be applied to the pixels PX through the scan lines SL1 to SLm, where m is a positive integer. The scan signals may be applied to the pixels PX, sequentially.

The driver chip DDV may, in response to the data control signal, generate a plurality of data voltages corresponding to the image signals. The data voltages may be applied to the pixels PX through the data lines DL1 to DLn, where n is a positive integer. The emission driver EDV may generate a plurality of emission signals in response to the emission control signal. The emission signals may be applied to the pixels PX through the emission lines EL1 to Elm, where m is a positive integer.

The pixels PX may be provided with the data voltages in response to the scan signals. The pixels PX may, in response to the emission signals, display an image by emitting light with luminance corresponding to the data voltages. The emission time of the pixels PX may be controlled by the emission signals.

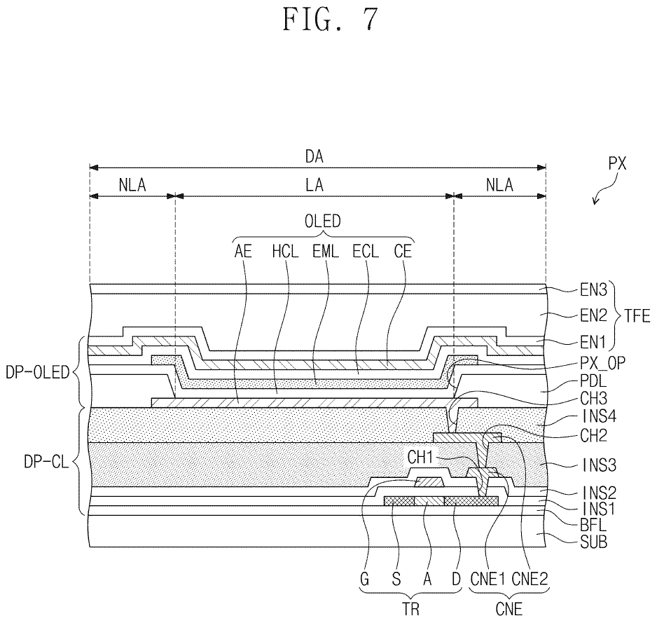

FIG. 7 is a cross sectional view of a pixel illustrated in FIG. 6.

Referring to FIG. 7, a pixel PX may be disposed on a substrate SUB. The pixels PX may include a transistor TR and a light-emitting element OLED. The light-emitting element OLED may include a first electrode AE (or an anode), a second electrode CE (or a cathode), a hole control layer HCL, an electron control layer ECL, and a light-emitting layer EML.

The transistor TR and the light-emitting element OLED may be disposed on the substrate SUB. One transistor TR is exemplarily illustrated. In some embodiments, the pixel PX may include a plurality of transistors and at least one capacitor for driving the light-emitting element OLED.

A display region DA may include an emission region LA corresponding to each of the pixels PX and a non-emission region NLA surrounding the emission region LA. The light-emitting element OLED may be disposed in the emission region LA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or metal oxide.

The semiconductor pattern may be doped with an N-type dopant or a P-type dopant. The semiconductor pattern may include a heavily doped region and a lightly doped region. The heavily doped region may have a higher conductivity than the lightly doped region, and may substantially serve as a source electrode and a drain electrode of the transistor TR. The lightly doped region may substantially correspond to an active (or a channel) of the transistor.

A source region S, a channel region A, and a drain region D of the transistor TR may be formed from the semiconductor pattern. A first insulation layer INS1 may be disposed on the semiconductor pattern. A gate electrode G of the transistor TR may be disposed on the first insulation layer INS1. The gate electrode G may overlap the channel region A.

A second insulation layer INS2 may be disposed on the gate electrode G.

A connection electrode CNE may include a first connection electrode CNE1 and a second connection electrode CNE2 for connecting the transistor TR and the light-emitting element OLED. The first connection electrode CNE1 may be disposed on the second insulation layer INS2, and connected to the drain region D through a first contact hole CH1 that is defined in the first and second insulation layers INS1 and INS2.

A third insulation layer INS3 may be disposed on the first connection electrode CNE1. The second connection electrode CNE2 may be disposed on the third insulation layer INS3. The second connection electrode CNE2 may be electrically connected to the first connection electrode CNE1 through a second contact hole CH2 that is defined in the third insulation layer INS3.

A fourth insulation layer INS4 may be disposed on the second connection electrode CNE2. The layers from the buffer layer BFL to the fourth insulation layer INS4 may be defined as a circuit element layer DP-CL. The first to fourth insulation layers INS1 to INS4 may be inorganic layers or organic layers.

The first electrode AE may be disposed on the fourth insulation layer INS4. The first electrode AE may be connected to the second connection electrode CNE2 through a third contact hole CH3 that is defined in the fourth insulation layer INS4. A pixel-defining film PDL, in which an opening PX_OP for exposing a portion of the first electrode AE is defined, may be disposed on the first electrode AE and the fourth insulation layer INS4.

The hole control layer HCL may be disposed on the first electrode AE and the pixel-defining film PDL. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate a red color light, a green color light, or blue color light.

The electron control layer ECL may be disposed on the light-emitting layer EML and the hole control layer HCL. The electron control layer ECL may include an electron transport layer and an electron injection layer. The hole control layer HCL and the electron control layer ECL may be disposed in the emission region LA and the non-emission region NLA.

The second electrode CE may be disposed on the electron control layer ECL. The second electrode CE may be disposed in the pixels PX. The layer where the light-emitting element OLED is disposed may be defined as a display element layer DP-OLED.

A thin-film encapsulation layer TFE may be disposed on the second electrode CE to cover the pixel PX. The thin-film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulation layer, and protect the pixel PX from moisture/oxygen. The second encapsulation layer EN2 may include an organic insulation layer, and protect the pixel PX from foreign matters such as dust particles.

A first voltage may be applied to the first electrode AE through the transistor TR, and a second voltage may be applied to the second electrode CE. Holes and electrons injected into the light-emitting layer EML combine to form excitons, and when the excitons transition to a ground state, the light-emitting element OLED may emit light.

FIG. 8 is a plan view of the first pad area illustrated in FIG. 6.

Referring to FIG. 8, a first pad part PAD1 may include a plurality of pads PD, a plurality of panel dummy pads PDP1 and PDP2, and a plurality of alignment keys AK. The pads PD may include a plurality of input pads IPD and a plurality of output pads OPD. The input pads IPD may be disposed adjacent to an upper side of the first pad part PAD1. The output pads OPD may be disposed adjacent to a lower side of the first pad part PAD1. The input pads IPD may be connected to the second pad part PAD2 (see FIG. 6) through the connection wiring CTL. The output pads OPD may be connected to pixels through the data lines DL1 to DLn, where n is a positive integer (see FIG. 6). The pads PD may be connected to the driver chip DDV (see FIG. 6). This configuration of the first pad part PAD1 will be described in more detail below.

The pads PD may be arranged in a matrix form. The pads PD disposed in a central region of the first pad part PAD1 with respect to a second direction DR2 may have a rectangular shape. The pads PA disposed on left and right sides with respect to the central region of the first pad part PAD1 may have a parallelogram shape. In some embodiments, the pads PD disposed on the left and right sides with respect to the central region of the first pad part PAD1 may have a symmetrical shape.

The alignment keys AK may be spaced apart in the second direction DR2 from the input pads IPD. The alignment keys AK may be respectively adjacent to two sides, of the first pad part PAD1, which are opposite to each other in the second direction DR2. In an embodiment, the input pads IPD may be disposed between the alignment keys AK.

When the driver chip DDV is connected to a display panel DP, the alignment keys AK may be used such that the driver chip DDV is aligned with the display panel DP. For example, the driver chip DDV may be aligned with the display panel DP such that the alignment keys disposed in the driver chip DDV and the alignment keys AK of the display panel DP overlap each other, and then the driver chip DDV may be pressure bonded to the display panel DP and connected to the display panel DP.

The panel dummy pads PDP1 and PDP2 may be electrically separated from the circuit element layer DP-CL (see FIG. 3). The panel dummy pads PDP1 and PDP2 may include a first panel dummy pad PDP1 and a second panel dummy pad PDP2. The first panel dummy pad PDP1 and the second panel dummy pad PDP2 may be respectively disposed adjacent to two sides, of the first pad part PAD1, which are opposite to each other in the second direction DR2. The second panel dummy pad PDP2 may be spaced apart from the first panel dummy pad PDP1 in the second direction DR2. The first panel dummy pad PDP1 and the second panel dummy pad PDP2 may have shapes that are symmetrical in the second direction DR2. When viewed from the second direction DR2, the first and second panel dummy pads PDP1 and PDP2 may be disposed between the input pads IPD and the output pads OPD. The first panel dummy pad PDP1 may include a plurality of first pressure distribution pads PPD1 and a first alignment pad APD1. The first alignment pad APD1 and the first pressure distribution pads PPD1 may be adjacent to each other in a first direction DR1 and arranged in the first direction DR1. For example, the three first pressure distribution pads PPD1 are disposed, but the first panel dummy pad PDP1 may include at least one first pressure distribution pad PPD1 adjacent to the first alignment pad APD1.

The first alignment pad APD1 may be closer to the input pads IPD than the first pressure distribution pads PPD1. The first pressure distribution pads PPD1 may be closer to the output pads OPD than the first alignment pad APD1.

When the driver chip DDV is pressure bonded to the display panel DP so as to connect the driver chip DDV to the display panel DP, in embodiments where the first alignment pad APD1 is disposed, pressure may be concentrated on the first alignment pad APD1. When the driver chip DDV is pressure bonded to the display panel DP, the first pressure distribution pads PPD1 may distribute the pressure that may be concentrated on the first alignment pad APD1.

The first alignment pad APD1 may have a closed loop shape. When viewed on a plane, the first panel dummy pad PDP1 may include a dummy pad DPD disposed inside the first alignment pad APD1. The first alignment pad APD1 may surround the dummy pad DPD.

The first alignment pad APD1 may include a metal layer. The metal layer of the first alignment pad APD1 may provide location information when the driver chip DDV is aligned with the display panel DP. For example, the driver chip DDV may include an alignment pad corresponding to the first alignment pad APD1, and locations of the driver chip DDV and the display panel DP may be confirmed through the first alignment pad APD1. Thus, in several embodiments, the driver chip DDV and the display panel DP may be aligned with each other.

In some embodiments, a second alignment pad APD2 and the first alignment pad APD1 may have a closed loop shape. When viewed on a plane, the second panel dummy pad PDP2 may include a dummy pad DPD disposed inside the second alignment pad APD2. The second alignment pad APD2 may be disposed to surround the dummy pad DPD.

The second alignment pad ADP2 may include a metal layer, and the metal layer of the second alignment pad APD2 may provide location information when the driver chip DDV is aligned with the display panel DP. The driver chip DDV may be aligned with the display panel DP more easily by confirming the locations of the display panel DP and the driver chip DDV through the first and second alignment pads APD1 and APD2.

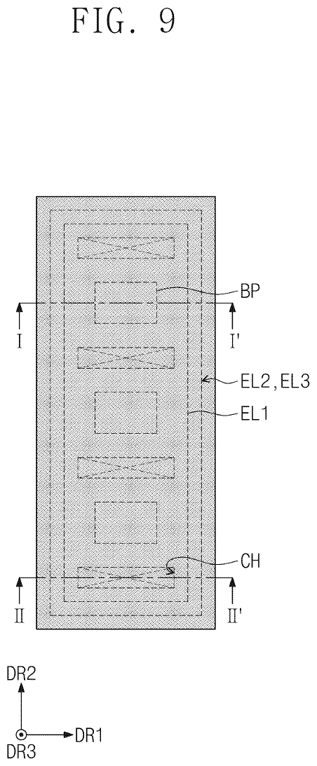

FIG. 9 is a planar configuration of a single pad illustrated in FIG. 8.

For example, a pad PD illustrated in FIG. 9 may be an input pad IPD or an output pad OPD. In some embodiments, it is exemplarily illustrated that the pad PD illustrated in FIG. 9 has a rectangular shape. However, the shape of the pad PD is not necessarily limited thereto.

Referring to FIG. 9, the pad PD may include a first electrode EL1, a second electrode EL2, a third electrode EL3, and a plurality buffer pads BP. The first, second, and third electrodes EL1, EL2, and EL3 may extend longer in a second direction DR2 than in a first direction DR1. When viewed on a plane, the first electrode EL1 may have a smaller area than each of the second and third electrodes EL2 and EL3. When viewed on a plane, the second electrode EL2 and the third electrode EL3 may have the same area.

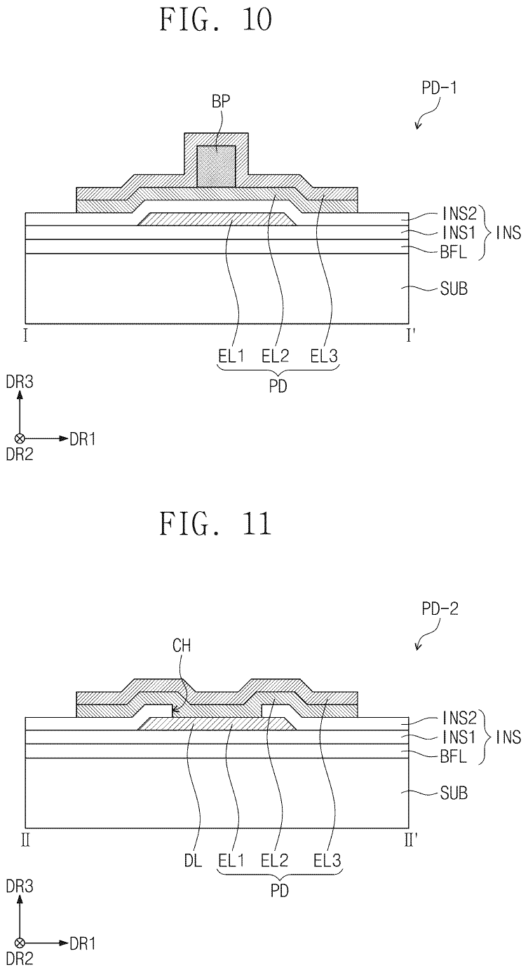

The first electrode EL1 may be connected to the second and third electrodes EL2 and EL3 through a plurality of contact holes CH. The contact holes CH may be arranged in a third direction DR3. The contact holes CH may extend longer in the first direction DR1 than in the second direction DR2. The contact holes CH may be defined by an insulation layer disposed between the first electrode EL1 and the second and third electrodes EL2 and EL3. The cross-sectional configuration of the pad PD will be described in more detail with reference to FIG. 11 below.

The buffer pads BP may be arranged in the second direction DR2. The buffer pads BP may be disposed between the contact holes CH so as not to overlap the contact holes CH.

FIG. 10 is a cross-sectional view taken along line I-I′ of FIG. 9.

Referring to FIG. 10, a pad PD may include a first electrode EL1, a second electrode EL2 disposed on the first electrode EL1, a third electrode EL3 disposed on the second electrode EL2, and a buffer pad BP disposed between the second electrode EL2 and the third electrode EL3. The first electrode EL1 may be disposed on a first insulation layer INS1. For example, the first electrode EL1 may be disposed at a same layer as the gate electrode G illustrated in FIG. 7. As used herein, the phrase, “disposed at a same layer” and similar phrases, may be used to mean that the two elements are formed as part of a same layer as one another. The first electrode EL1 may be formed by being patterned simultaneously with the same material as the gate electrode G. The second electrode EL2 may be disposed on the first electrode EL1. The second electrode EL2 may be disposed on a second insulation layer INS2. The third electrode EL3 may be disposed on the second electrode EL2.

The buffer pad BP may be disposed on the second electrode EL2 and the third electrode EL3 may be disposed on the second electrode EL2 to cover the buffer pad BP. For example, the buffer pad BP may be disposed between the second electrode EL2 and the third electrode EL3. The buffer pad BP may include an organic insulation layer. For example, the buffer pad BP may include an elastic polymer.

The second electrode EL2 may be formed by being patterned simultaneously with the same material as the first connection electrode CNE1 illustrated in FIG. 7. The third electrode EL3 may be formed by being patterned simultaneously with the same material as the second connection electrode CNE2 illustrated in FIG. 7. The second electrode EL2 and the first connection electrode CNE1 may be defined as a first source-drain electrode, and the third electrode EL3 and the second connection electrode CNE2 may be defined as a second source-drain electrode.

FIG. 11 is a cross-sectional view taken along line II-II′ of FIG. 9. Referring to FIG. 11, a second electrode EL2 may be disposed on a first electrode EL1, and the second electrode EL2 may be connected to the first electrode EL1 through a contact hole CH that is defined in a second insulation layer INS2. Since a third electrode EL3 is disposed on the second electrode EL2 to be in contact with the second electrode EL2, and the second electrode EL2 is in contact with the first electrode EL1 through the contact hole CH, the first to third electrodes EL1, EL2, and EL3 may be electrically connected to each other.

When a first pad PD-1 is an input pad, the first electrode EL1 may be connected to the connection line CNL. When the first pad PD-1 is an output pad, the first electrode EL1 may be connected to the data lines DL1 to DLn, where n is a positive integer. However, an embodiment of the disclosure is not necessarily limited thereto, and the second electrode EL2 may be electrically connected to the connection line CNL or the data lines DL1 to DLn, where n is a positive integer.

FIG. 12 is a cross-sectional view of a first pressure distribution pad taken along line x-x′ of FIG. 8.

Referring to FIG. 12, a first pressure distribution pad PPD1 may include a (1-1)-th electrode EL1-1, a (2-1)-th electrode EL2-1 disposed on the (1-1)-th electrode EL1-1, a (3-1)-th electrode EL3-1 disposed on the (2-1)-th electrode EL2-1, and a dummy buffer pad DBP disposed between the (2-1)-th electrode EL2-1 and the (3-1)-th electrode EL3-1.

The (1-1)-th electrode EL1-1 may be disposed on a first insulation layer INS1. In some embodiments, the (1-1)-th electrode EL1-1 may be disposed at a same layer as the gate electrode G illustrated in FIG. 7. The (2-1)-th electrode EL2-1 may be disposed on the (1-1)-th electrode EL1-1. The (2-1) electrode EL2-1 may be disposed on a second insulation layer INS2. The (3-1)-th electrode EL3-1 may be disposed on the (2-1)-th electrode EL2-1.

The dummy buffer pad DBP may be disposed on the (2-1)-th electrode EL2-1 and the (3-1)-th electrode EL3-1 may be disposed on the (2-1)-th electrode EL2-1 to cover the dummy buffer pad DBP. In some embodiments, the dummy buffer pad DBP may be disposed between the (2-1)-th electrode EL2-1 and the (3-1)-th electrode EL3-1. The dummy buffer pad DBP may include an organic insulation layer. For example, the dummy buffer pad DBP may include a polymer that has elasticity.

In some embodiments, a second pressure distribution pad PPD2 may also have the same configuration as the first pressure distribution pad PPD1.

The (1-1)-th electrode EL1-1 may be formed by being patterned simultaneously with the same material as the first electrode EL1. In some embodiments, the (2-1)-th electrode EL2-1 may be formed by being patterned simultaneously with the same material as the second electrode EL2, and the (3-1)-th electrode EL3-1 may be formed by being patterned simultaneously with the same material as the third electrode EL3.

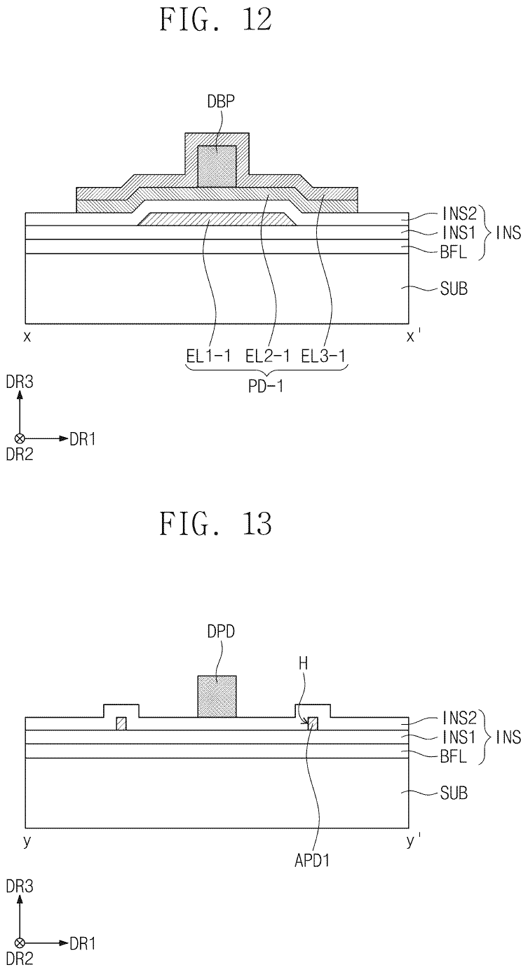

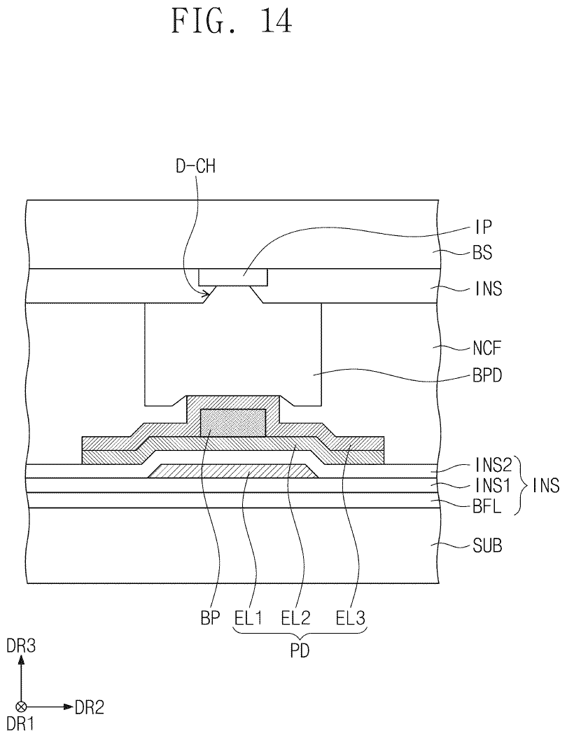

FIG. 13 is a cross-sectional view of a first alignment pad and a dummy pad taken along line y-y′ of FIG. 8.

Referring to FIG. 13, a first alignment pad APD1 may include a metal layer. For example, the first alignment pad APD1 may be formed of a metal layer. The first alignment pad APD1 may be disposed on a first insulation layer INS1. The first alignment pad APD1 may be disposed at a same layer as the gate electrode G illustrated in FIG. 7. The first alignment pad APD1 may be formed by being patterned simultaneously with the same material as the gate electrode G. The first alignment pad APD1 may be disposed at a same layer as the first electrode EL1 and the (1-1)-th electrode EL1-1. In some embodiments, the first alignment pad APD1 may be formed by being patterned simultaneously with the same material as the first electrode EL1 and the (1-1)-th electrode EL1-1.

A second insulation layer INS2 may be disposed on the first alignment pad APD1. A dummy pad DPD may be disposed on the second insulation layer INS2. In some embodiments, the dummy pad DPD may be disposed at a layer above the first alignment pad APD1. The dummy pad DPD may be disposed at a same layer as the buffer pad BP. The dummy pad DPD may include the same material as the buffer pad BP.

A hole H may be defined in the first alignment pad APD1, and the dummy pad DPD may be disposed in the hole H. In some embodiments, since the dummy pad DPD is disposed within a region defined by the first alignment pad APD1, the first alignment pad APD1 may be disposed to surround the dummy pad DPD. The region defined by the first alignment pad APD1 may be defined as a window region.

When viewed on a plane, the first alignment pad APD1 may surround the dummy pad DPD. The dummy pad DPD may include an organic insulation layer. For instance, the dummy pad DPD may include a polymer. The dummy pad DPD may have elasticity and may be deformed by compressive force. A thickness of the first alignment pad APD1 may be smaller than a thickness of the dummy pad DPD. In some embodiments, the first alignment pad APD1 might not be electrically connected to pixels PX. For example, the first alignment pad APD1 may be electrically disconnected from the Pixels PX.

In some embodiments, a second alignment pad APD2 may also have the same configuration as the first alignment pad APD1.

FIG. 14 is a view illustrating a pad disposed on a display panel illustrated in FIG. 10 coupled to a chip pad disposed on a driver chip, according to some embodiments of the disclosure.

Referring to FIG. 14, a driver chip DDV may include a base layer BS, a chip pad IP disposed under the base layer, and a bump pad BPD disposed under the chip pad IP. An insulation layer INS may be disposed under the base layer BS and the chip pad IP, and the bump pad BPD may be disposed under the insulation layer INS. The bump pad BPD may be connected to the chip pad IP through a contact hole D-CH defined in the insulation layer INS. In some embodiments, various elements and wiring may be disposed on the base layer BS.

The bump pad BPD may be disposed between the chip pad IP and a pad PD. When the driver chip DDV is connected to a display panel DP, the driver chip DDV may be aligned with the display panel DP by the alignment key AK and the first and second alignment pads APD1 and APD2. In some embodiments, the bump pad BPD and the chip pad IP may overlap the pad PD. An alignment process may be performed by a camera. For example, an alignment camera may be disposed under the display panel DP, and it may be confirmed by the camera whether an alignment key and an alignment pad of the driver chip DDV are aligned with the alignment key AK and the first and second alignment pads APD1 and APD2 of the display panel DP.

Then, the driver chip DDV may be pressure bonded to the display panel DP through a pressurization process. During the pressurization process, the bump pad BPD may be pressurized toward the pad PD, and connected to the pad PD. During the pressurization operation, a buffer pad BP may cushion the compression of the bump pad BPD.

The driver chip DDV may be pressurized toward the display panel DP, and the pad PD and the chip pad IP may be electrically connected by the bump pad BPD. As a result, the driver chip DDV may be connected to the display panel DP.

In some embodiments, the bump pad BPD may be electrically connected to the pads PD. The pads PD may include a first electrode EL1, a second electrode EL2 disposed on the first electrode EL1, a third electrode EL3 disposed on the second electrode EL2 to be connected to the second electrode EL2, and the buffer pad BP between the second electrode EL2 and the third electrode EL3.

When the bump pad BPD is pressure bonded to the buffer pad BP, the buffer pad BP may contract in a direction perpendicular to an upper surface of the display panel DP. The upper surface of the display panel DP may have a plane defined by a first direction DR1 and a second direction DR2 intersecting the first direction DR1. A dummy pad DPD may be adjacent to an edge of a first pad part PAD1 in the second direction DR2. The bump pad BPD may be disposed on a third electrode EL3 of a corresponding pad PD among the pads PD and connected to the third electrode EL3 of the corresponding pad PD.

The buffer pad BP may be formed of the same material as the dummy pad DPD. The buffer pad BP and the chip pad IP may be coupled by the bump pad BPD. Regions other than the region where the buffer pad BP and the chip pad IP are coupled may be coupled through a non-conductive film NCF.

Since the driver chip DDV and the display panel DP may be opaque, it may be difficult to confirm, from the upper surface or a rear surface of the display panel DP, whether the pad PD and the chip pad IP are properly aligned. In some embodiments, it may be possible to estimate whether the pad PD and the chip pad IP are properly aligned by confirming the coupling of the first alignment pad APD1 illustrated in FIG. 12 and the chip pad IP. Estimating of whether the pad PD and the chip pad IP are properly aligned will be described in more detail below.

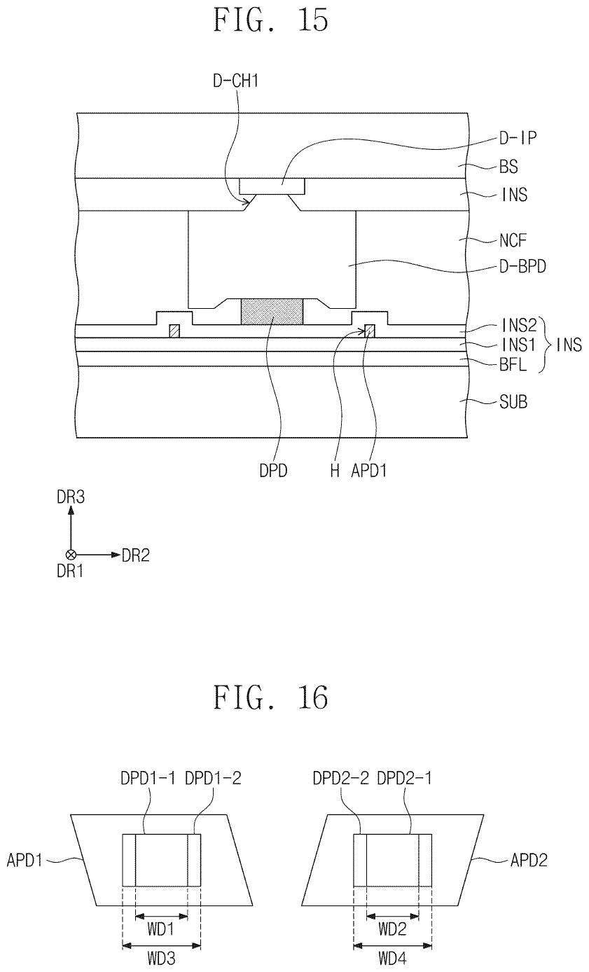

FIG. 15 is a view illustrating the first alignment pad illustrated in FIG. 13 coupled to a chip pad disposed on a driver chip, according to some embodiments of the disclosure.

Referring to FIG. 15, a driver chip DDV may include a dummy chip pad D-IP disposed under a base layer BS and a dummy bump pad D-BPD disposed under the dummy chip pad D-IP. The dummy chip pad D-IP might not be electrically connected to the driver chip DDV. An insulation layer INS may be disposed under the dummy chip pad D-IP, and the dummy bump pad D-BPD may be electrically connected to the dummy chip pad D-IP through a contact hole D-CH1 defined in the insulation layer INS.

The driver chip DDV may include the dummy bump pad D-BPD connected to a dummy pad DPD. When the dummy bump pad D-BPD is pressure bonded to the dummy pad DPD, the dummy pad DPD may contract in a direction perpendicular to an upper surface of a display panel DP. For example, when the dummy bump pad D-BPD is pressure bonded to the dummy pad DPD, the dummy pad DPD may expand in a second direction DR2. The dummy pad DPD and the dummy chip pad D-IP may be coupled by the dummy bump pad D-BPD. Regions other than the region where the dummy pad DPD and the dummy chip pad D-IP are coupled may be coupled through a non-conductive film NCF.

When viewed from a third direction DR3, the dummy pad DPD may, without being covered, be visible by a hole H defined in a first alignment region APD1. In some embodiments, when viewed from the third direction DR3, a location of the dummy chip pad D-IP which is coupled to the dummy pad DPD may be determined.

When the driver chip DDV is disposed on the display panel DP, it may be difficult to confirm whether the driver chip DDV is properly aligned above the display panel DP since the driver chip DDV and the display panel DP include various elements. Since the substrate SUB (see FIG. 3) of the display panel DP is transparent, an alignment state of the driver chip DDV may be measured from a rear surface of the display panel DP.

Light may be applied on the rear surface of the display panel DP by using a light source below the display panel DP. The light applied on the rear surface of the display panel DP may be reflected and incident on a measuring device. For example, the measuring device may be a device such as a camera which takes pictures of the rear surface of the display panel DP.

In some embodiments, since a window region is defined by holes H of the first and second alignment pads APD1 and ADP2 (see FIG. 15) of the display panel DP, the measuring device may measure an amount of change in the dummy pad DPD under the display panel DP. For example, the amount of change in the dummy pad DPD may be measured by change in size of the dummy pad DPD before and after a coupling process.

FIG. 16 illustrates first and second dummy pads captured by a measuring device.

Referring to FIG. 8, a first alignment pad APD1 and a second alignment pad APD2 may face each other with pads PD interposed therebetween, and may be symmetrical to each other. In some embodiments, flatness of a display panel DP may be confirmed by measuring an amount of change in first and second dummy pads DPD1-2 and DPD2-2 after pressure bonding rather than in first and second dummy pads DPD1-1 and DPD2-1 before the pressure bonding.

Referring to FIG. 16, the first and second dummy pads DPD1-2 and DPD2-2 after the pressure bonding may have a greater area than the first and second dummy pads DPD1-1 and DPD2-1 before the pressure bonding. Widths WD3 and WD4 of the first and second dummy pads DPD1-2 and DPD2-2 after the pressure bonding may be greater than widths WD1 and WD2 of the first and second dummy pads DPD1-1 and DPD2-1 before the pressure bonding. For example, in some embodiments, the widths WD1 and WD2 of the first and second dummy pads DPD1-1 and DPD2-1 before the pressure bonding and the widths WD3 and WD4 of the first and second dummy pads DPD1-2 and DPD2-2 after the pressure bonding may be lengths extending in a second direction DR2.

For example, a ratio of the width WD1 of the first dummy pad DPD1-1 before the pressure bonding to the width WD3 of the first dummy pad DPD1-2 after the pressure bonding may be defined as an amount of change in the first dummy pad. In some embodiments, a ratio of the width WD2 of the second dummy pad DPD2-1 before the pressure bonding to the width WD4 of the second dummy pad DPD2-2 after the pressure bonding may be defined as an amount of change in the second dummy pad.

In FIG. 16, the amount of change in the first and second dummy pads is measured, with respect to the second direction DR2, in the widths WD1 and WD2 of the first and second dummy pads DPD1-1 and DPD2-1 before the pressure bonding and the widths WD3 and WD4 of the first and second dummy pads DPD1-2 and DPD2-2 after the pressure bonding. However, an embodiment of the disclosure is not necessarily limited thereto, and the amount of change may be measured in change in width and change in area in a first direction DR1.

When an error rate between a change rate in the first dummy pad and a change rate in the second dummy pad is about 10% or less, the flatness of the display panel DP may be determined to be normal. When the error rate between the change rate in the first dummy pad and the change rate in the second dummy pad is greater than about 10%, the flatness of the display panel DP may be determined to be distorted. A judgement criteria may be set, for example, whether a difference in the amount of change between the first and second dummy pads DPD1-2 and DPD2-2 is about 10% of the amount of change in the first dummy pad DPD1-2. In an embodiment, the judgement criteria may be set as whether a difference in the amount of change between the first and second dummy pads DPD1-2 and DPD2-2 is about 10% of the amount of change in the second dummy pad DPD2-2.

Since the pads PD (see FIG. 15) are opaque, it may be difficult to confirm, from the rear surface of the display panel DP, whether the alignment is properly performed. In some embodiments, it may be possible to estimate whether the alignment of the pads PD is properly performed or not on the basis of the change rate in the first dummy pad and the change rate in the second dummy pad.

For example, the pads PD may be divided into stages according to error rates between the change rate in the first dummy pad and the change rate in the second dummy pad, and may be possible to estimate a degree of the alignment of the pads PD at each corresponding stage. In some embodiments, it may be possible to estimate an amount of change in the buffer pad BP (see FIG. 15) before and after the pressure bonding, on the basis of the change rate in the first dummy pad and the change rate in the second dummy pad even without a cross-sectional analysis of the pads PD.

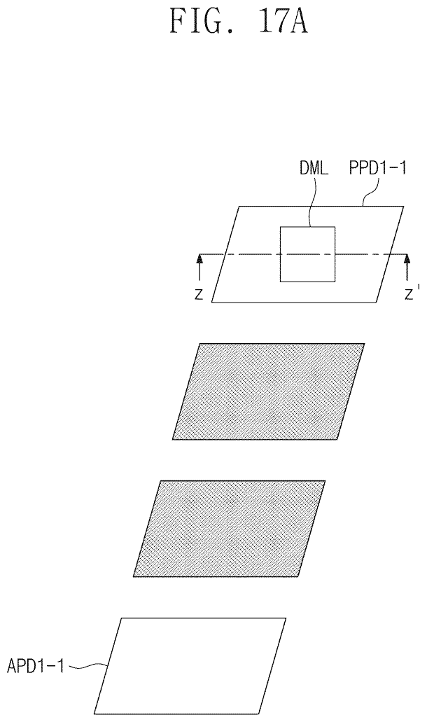

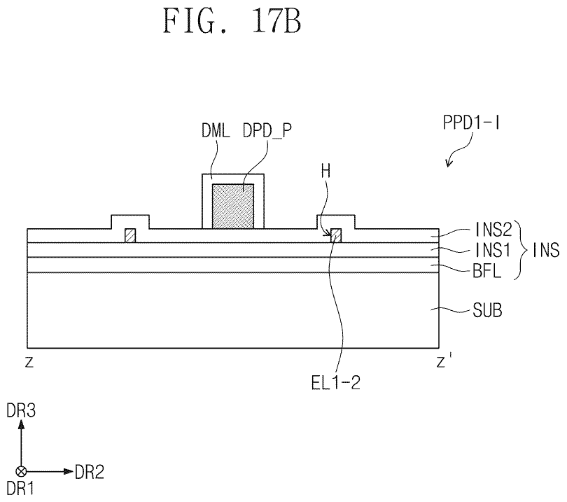

FIG. 17A illustrates a first dummy panel pad according to an embodiment of the disclosure, and FIG. 17B illustrates a cross section of a first pressure distribution pad taken along line z-z′ of FIG. 17A.

Referring to FIG. 17A, a plurality of first pressure distribution pads PPD1-1 and a first alignment pad APD1-1 may be disposed. A window region may be defined in at least one of the plurality of first pressure distribution pads PPD1-1. The first pressure distribution pad PPD1-1 in which the window region is defined may be used for measuring the flatness of a display panel DP. For example, in an embodiment, the first alignment pad APD1-1 may be used exclusively for measuring the alignment of the display panel DP.

Referring to FIG. 17B, in a first pressure distribution pad PPD1-1, a buffer layer BFL may be disposed on a substrate SUB, and a first insulation layer INS1 may be disposed on the buffer layer BFL. A (1-2)-th electrode EL1-2 may be disposed on the first insulation layer INS1. A hole H may be defined in the (1-2)-th electrode EL1-2, and a window region may be defined by the hole H. A second insulation layer INS2 may be disposed on the (1-2)-th electrode EL1-2 and the first insulation layer INS1 and connected through the hole H. A dummy pad DPD_P may be disposed on the second insulation layer INS2. A dummy metal layer DML may be disposed on the dummy pad DPD_P.

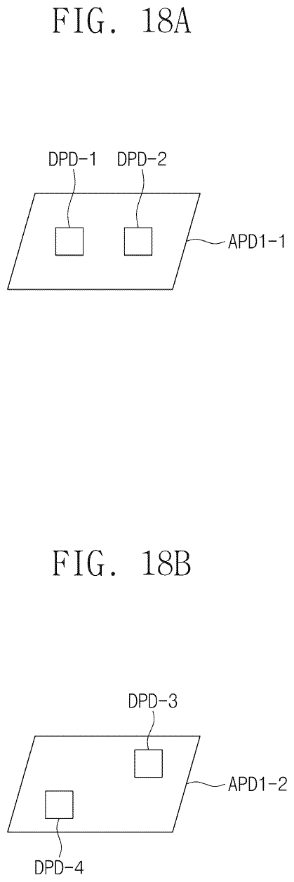

FIGS. 18A and 18B illustrate a first dummy pad according to an embodiment of the disclosure.

Referring to FIGS. 18A and 18B, dummy pads DPD-1, DPD-2, DPD-3, and DPD-4 may be provided in plural to window regions defined by first alignment pads APD1-1 and APD1-2.

For example, FIG. 18A illustrates that two dummy pads DPD-1 and DPD-2 are spaced apart from each other, but the number and arrangement of the dummy pads DPD-1 and DPD-2 are not necessarily limited thereto.

For example, FIG. 18B illustrates that the dummy pads DPD-3 and DPD-4 are arranged diagonally, but the number and arrangement of the dummy pads DPD-3 and DPD-4 are not necessarily limited thereto.

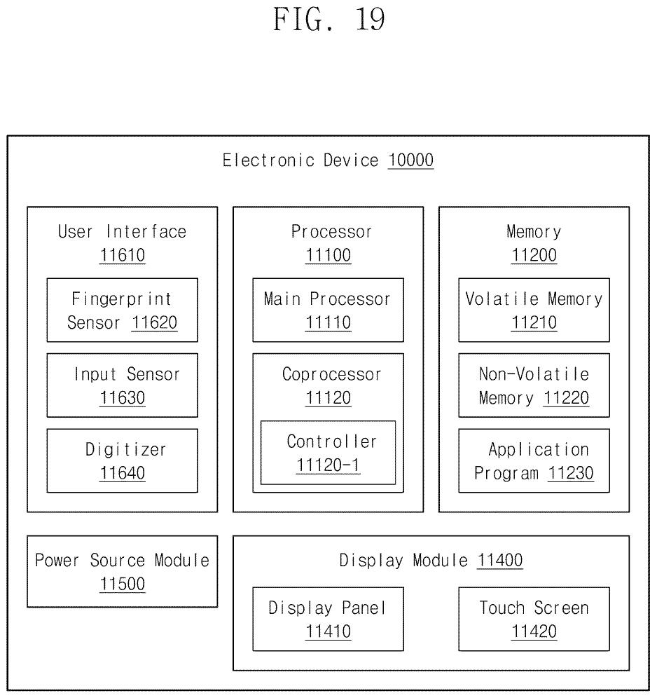

FIG. 19 is a diagram illustrating an electronic device according to an embodiment of the disclosure. Referring to FIG. 10, the electronic device 1000 according to one embodiment of the present invention may output various information (e.g., images, text, music, etc.) through a display module 1140, which, for example, may correspond to the display device DD shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

In a display device, an electronic apparatus, and an electronic device according to an embodiment of the disclosure, it may be possible to determine whether the flatness of a display panel is distorted by measuring an amount of deformation in an insulation layer.

Those skilled in the art will recognize that the present disclosure can be practiced in other specific ways without departing from its technical spirit or essential characteristics. Therefore, the described embodiments should be regarded as illustrative rather than being restrictive in all aspects. Although embodiments of the present disclosure have been described with reference to the accompanying drawings, the disclosure is not necessarily limited to these embodiments and may be implemented in various forms.

What is claimed is:

1. A display device, comprising:
a display panel including a plurality of pixels;
a pad area including a plurality of pads disposed therein;
a driver chip disposed on the pad area and electrically connected to the plurality of pads and to the plurality of pixels;
a dummy pad spaced apart from the plurality of pads; and
an alignment pad surrounding the dummy pad.

2. The display device of claim 1, wherein the alignment pad comprises a metal layer.

3. The display device of claim 1, wherein the alignment pad is disposed below the dummy pad.

4. The display device of claim 1, wherein the dummy pad comprises a polymer.

5. The display device of claim 1, wherein the alignment pad comprises a same material as a gate electrode of a transistor of one of the plurality of pixels, and wherein the alignment pad and the gate electrode are disposed within a same layer.

6. The display device of claim 1, wherein a thickness of the alignment pad is less than a thickness of the dummy pad.

7. The display device of claim 1, wherein the alignment pad is electrically disconnected from the plurality of pixels.

8. The display device of claim 1, wherein the driver chip comprises:
bump pads electrically connected to the plurality of pads; and
a dummy bump pad electrically connected to the dummy pad.

9. The display device of claim 8, wherein the dummy bump pad is pressure bonded to the dummy pad and the dummy pad is contracted in a direction perpendicular to an upper surface of the display panel.

10. The display device of claim 8, wherein an upper surface of the display panel is a plane defined by a first direction and a second direction intersecting the first direction, and the dummy pad is adjacent to an edge of the pad area in the second direction.

11. The display device of claim 10, wherein the dummy bump pad is pressure bonded to the alignment pad and the dummy pad is expanded in the second direction.

12. The display device of claim 8, wherein each of the plurality of pads comprises:
a first electrode;
a second electrode disposed on the first electrode and electrically connected to the first electrode;
a third electrode disposed on the second electrode and electrically connected to the second electrode; and
a buffer pad disposed between the second electrode and the third electrode,
wherein each of the bump pads is disposed on a third electrode of a corresponding pad among the plurality of pads and is electrically connected to the third electrode of the corresponding pad of the plurality of pads.

13. The display device of claim 12, wherein the dummy pad comprises a same material as the buffer pad.

14. The display device of claim 12, further comprising a pressure distribution pad adjacent to the dummy pad.

15. The display device of claim 14, wherein the pressure distribution pad comprises:
a (1-1)-th electrode;
a (2-1)-th electrode disposed on the (1-1)-th electrode;
a (3-1)-th electrode disposed on the (2-1)-th electrode; and
a dummy buffer pad disposed between the second electrode and the third electrode.

16. The display device of claim 1, further comprising a dummy metal layer disposed on the dummy pad.

17. The display device of claim 1, wherein the dummy pad is provided in plural in a window region defined by the alignment pad.

18. The display device of claim 1, wherein the dummy pad is elastic and is configured to be deformed by compressive force.

19. An electronic apparatus, comprising:
a display device including a first hole region configured to pass light therethrough;
an electro-optical circuit disposed under the display device to overlap the first hole region, and configured to receive a light signal; and
a case configured to accommodate the display device and the electro-optical circuit,
wherein the display device includes:
a display panel including a plurality of pixels and a pad area electrically connected to the plurality of pixels, and
a driver chip disposed on the pad area and electrically connected to the pad area, and
wherein the pad area includes:
a plurality of pads electrically connected to the plurality of pixels and to the driver chip,
a dummy pad spaced apart from the plurality of pads, and
an alignment pad surrounding the dummy pad.

20. An electronic device, comprising:
a display device including a first hole region configured to allow light to pass through;
an electro-optical circuit disposed under the display device to overlap the first hole region, and configured to receive a light signal; and
a case accommodating the display device and the electro-optical circuit,
wherein the display device includes:
a display panel including a plurality of pixels and a pad area electrically connected to the plurality of pixels, and
a driver chip disposed on the pad area and electrically connected to the pad area, and
wherein the pad area includes:
a plurality of pads electrically connected to the plurality of pixels and to the driver chip,
a dummy pad spaced apart from the plurality of pads, and
an alignment pad surrounding the dummy pad.
